(19) United States
(12) Patent Application Publication
(10) Pub. No.: US 2008/0192389 A1
(43) Pub. Date: Aug. 14, 2008

(54) ARC SUPPRESSION DEVICE, SYSTEM AND METHODS FOR LIQUID INSULATED ELECTRICAL APPARATUS

(76) Inventors: Frank John Muench, Waukesha, WI (US); John Fredrick Banting, Waukesha, WI (US); Stewart Durian, Sussex, WI (US)

Correspondence Address: KING & SPALDING LLP, 1180 PEACHTREE STREET, ATLANTA, GA, 30309-3521, US

(21) Appl. No.: 11/673,913

(22) Filed: Feb. 12, 2007

(51) Int. Cl. H02H 3/00; G01R 19/00

(52) U.S. Cl. 361/5; 324/76.11; 361/3

(57) ABSTRACT

Arc suppression systems, devices and methods for avoiding undesirable arcing conditions inside a liquid-filled tank of a high-voltage electrical apparatus.

### BACKGROUND OF THE INVENTION

This invention relates generally to high-voltage electrical apparatus for electrical power transmission and distribution systems, and more specifically to arc suppression systems for under-fluid electrical components.

Electrical power systems operated by electrical utility firms and the like typically include a large number of transformers, capacitor banks, reactors, motors, generators and other major pieces of electrical equipment often interconnected with heavy duty cabling and switching devices for connecting and disconnecting the equipment to the network. Protective devices, including but not limited to fuses, breakers, limiters, arrestors, and protective relay devices are typically connected to the major pieces of equipment and are designed to open and close circuitry in the power system when fault conditions occur to protect the system from damage. Temporary power losses may occur when such protective devices operate, and avoiding or minimizing downtime of affected circuitry and loads is of primary concern to power system operators.

A failure of the major pieces of equipment, such as power distribution transformers and capacitors, and associated switchgear and switching devices, may require costly and time consuming delays in restoring power to customers. Failure of the major pieces of equipment may also present hazardous conditions to nearby persons and equipment. This is especially true for equipment and switchgear including components immersed in liquid dielectric fluids within a tank.

### BRIEF DESCRIPTION OF THE DRAWINGS

FIG. 1 is a schematic representation of an electrical apparatus and arc suppression system according to an exemplary embodiment of the invention.

FIG. 2 is a schematic representation of a first embodiment of an electrical apparatus and arc suppressor for the system shown in FIG. 1.

FIG. 3 is a cross sectional view of the arc suppressor shown in FIG. 2.

FIG. 4 is a schematic representation of a second exemplary embodiment of an electrical apparatus and arc suppressor for the system shown in FIG. 1.

FIG. 5 is an exemplary control algorithm flowchart for an arc suppression system according to the invention.

### DETAILED DESCRIPTION OF THE INVENTION

Improvements in electrical equipment and apparatus for high-voltage applications, such as applications carrying more than 1000 volts in a power distribution network, are provided in exemplary embodiments of the present invention. In order to appreciate the benefits of the invention to its full extent, the disclosure herein will be segmented into different parts. Part I discusses known electrical equipment and apparatus and problems associated therewith. Part II discusses conventional protective devices and techniques for the equipment and apparatus discussed in Part I. Part III discusses inventive arc suppression systems and component devices, and Part IV discloses exemplary control methods for operating the arc suppression devices of Part III to overcome the problems and disadvantages discussed in Part I and Part II.

### I. Introduction to Liquid Dielectric Insulated Equipment

High-voltage electrical equipment and apparatus are known that includes active elements or components immersed in a liquid dielectric fluid, as opposed to air or gaseous dielectric mediums, to provide dielectric withstand capability, cooling and arc interruption properties for the active elements or components of the equipment or apparatus.

More specifically, switchgear utilizing liquid dielectric fluids is known. If an arc occurs inside of a fluid filled tank, however, a very high-pressure transient may occur that can cause tank seams, welds or gaskets to break or rupture and present hazardous conditions including fire at locations external to the tank. High current arcs within the headspace of the tank near the top of the liquid or over the top of the liquid may result in additional pressure being created in the headspace that can cause the tank to rupture.

Some known high-voltage electrical components may employ integral switching elements in operation. For example, power distribution transformers are known that include core and coil assemblies that are immersed in a dielectric liquid within a tank, and switching elements for the core and coil assemblies are also immersed in the dielectric liquid within the tank. The switches are therefore operated in the same insulating liquid as the transformer. When the switches break load current, carbonaceous by-products may be created, which potentially could reduce the dielectric withstand capability of the transformer.

Additionally such transformers typically have a headspace of two to six cubic feet of air over the liquid surrounding the core-coil. Should the switches in the tank fail for any reason, the resulting arc within the insulating liquid surrounding the switches can generate large amounts of gas. This may result in the rupture of the tank.

In particular, if a failure occurs internal to a transformer tank, an electrical arc may result inside the tank and generate intense heat. If an electrical breakdown occurs in a tank, an arc may result. The arc may produce arc plasma. Fault current may flow through the arc plasma, generating heat, and temperatures of 5,000 to 15,000° K. within the arc may result. Heat associated with arcing may cause heating and vaporization of the dielectric fluid in contact with the arc, resulting in very high pressures as the fluid is vaporized, ionized and heated by the arc. The arc has an electrical resistance to the current flowing through the plasma, resulting in an arc-voltage. The product of fault current and the arc voltage integrated over time, sometimes referred to as the arc energy, is a measure of the energy released in the tank by arcing conditions.

Resultant pressure within the tank attributable to the arc energy may exceed the pressure withstand capability of the tank and cause the tank to rupture. Fluid spillage external to the tank, and potentially fire and flame when flammable dielectric fluids are utilized, may result outside the tank.

### II. Conventional Protective Schemes

Traditionally, protective devices such as fuses and breakers have been used to control electrical arcing in high-voltage electrical equipment, indirectly limiting pressure build up within a tank. However, such protective devices must be connected to the incoming and outgoing cables that are connected to the equipment. In the case of transformers, these cable leads carry all of the current in the cable system, in addition to the core and coil assembly of the transformer.

Typically, protective devices are connected to transformers that have ampere ratings sufficient to protect only the core and coil assembly. The protective devices may be resettable or replaceable after they operate due to an overload of the transformer or secondary fault outside the transformer. Other known protective devices operate only when the core/coil assembly of the transformer fails, in which case the transformer itself must be replaced when the protective devices operate.

When fuses are used as the protective devices, if a fuse protecting the core and coil assembly operates, the associated cable loop normally remains in service. For many applications, however, the magnitude of the load current in the cable system is often so large that there are few or no fuses available that can carry the normal system current ranging from 1 to 38 kV. Fuses that can carry this current are very large and are expensive. Additionally, fuses with adequate ampere ratings to carry this current may not interrupt the circuit in failure conditions quickly enough to prevent rupturing of the tank.

Fuses also have an additional drawback in that they respond to the current flowing through the fuse. If a cable fault or dig-in occurs that damages the cable; the fuse may respond and operate to clear the fault, but it is generally not possible to immediately know whether the fuse opened due to current from a fault condition within the transformer (the area of concern from the perspective of avoiding tank rupture) or whether the fuse opened due to current from a fault condition outside the transformer. Whether fault conditions have occurred inside or outside the transformer is consequential to what action is needed to restore electrical power to the cable loop. If the fuse operates on a fault outside the transformer, such as in the cables themselves, the fuse, and perhaps one or more of the cables, would need to be replaced before the cable loop can be restored to service, while if the fuse operates on a fault inside the transformer, the transformer and the fuse must be replaced.

### III. Embodiments of the Invention

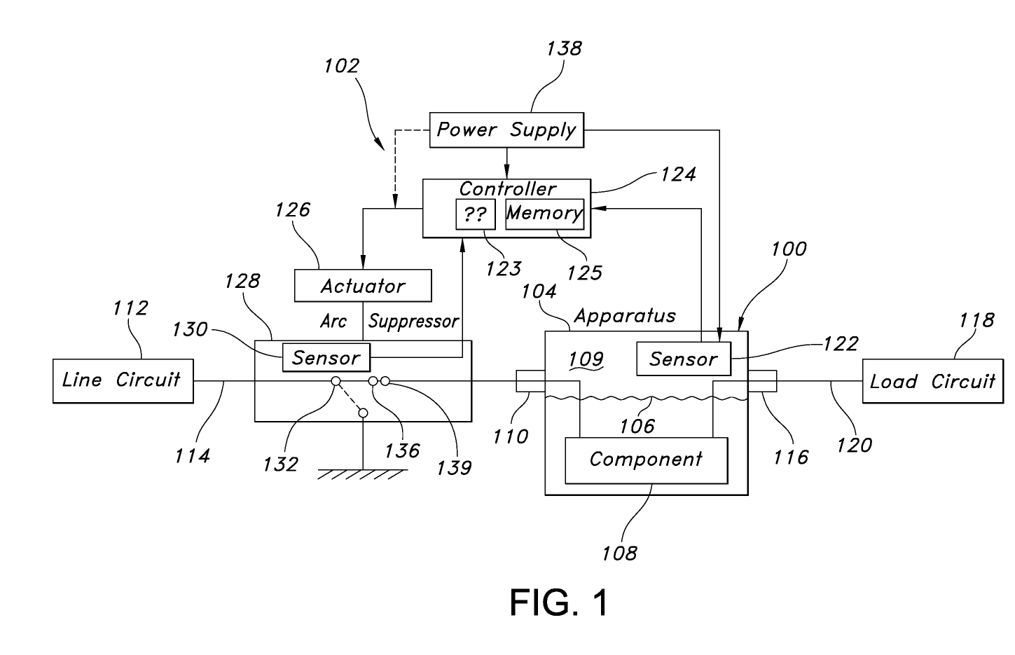

FIG. 1 is a schematic representation of an electrical apparatus 100 and arc suppression system 102 according to an exemplary embodiment of the invention, which overcomes the problems and disadvantages noted above. The electrical apparatus 100 includes an enclosure or housing that is sometimes referred to as a tank 104. The apparatus 100 may be, for example, a high-voltage transformer or high-voltage switchgear. The tank 104 is partly filled with a liquid dielectric fluid 106, and a component 108 or component assembly is contained within the tank 104, and at least a portion of the component or component assembly 108 is immersed in the fluid 106 in the tank 104. More than one tank may be provided in the apparatus 100 to contain different components 108.

The dielectric fluid 106 in the tank(s) 104 may be a liquid dielectric fluid including, for example, base ingredients such as mineral oils or vegetable oils, synthetic fluids such as polyolesters, silicone fluids, mixtures of the same, or other insulative fluids known in the art. One liquid dielectric fluid that is suitable and advantageous as the dielectric fluid 106 is formulated from edible seed soil and food grade performance additives and has a high fire point, one example being ENVIROTEMP® FR3™ fluid available from Cooper Power Systems of Waukesha, Wis., although this particular fluid is by no means required. As used herein, the term “liquid” shall refer to the above-identified liquids and other liquids providing dielectric withstand capability, cooling and arc interruption properties.

Optionally, a portion 109 that is not occupied by the dielectric fluid 106 in the tank 104, sometimes referred to as headspace of the tank 104 may be filled with nitrogen, another other gas, or combination of gases that will not burn when combined with gaseous by-products produced during arcing. In such a manner, an inert gas blanket may be provided in the tank 104. The inert gas blanket overlies the dielectric fluid 106 in the headspace 109. Also optionally, one or more pressure relief devices may be provided in the construction of the tank 104 to regulate pressure in the tank 104. As one example, the pressure relief device may be a known spring-loaded valve that is forced open by specified pressure conditions. As such, pressure conditions within the tank 104 that exceed a certain threshold level, dependent upon the configuration and characteristics of the pressure relief device, may cause the pressure relief device to open and relieve pressure from the interior of the tank 104 to the ambient environment external to the apparatus 100. As the pressure within the tank 104 returns to the threshold level, the pressure relief device may return to a closed state.

Line-side, high-voltage connectors or bushings 110 may be provided for mechanical and electrical connection to line-side circuitry 112 with a line-side cable 114. Load-side, high-voltage connectors or bushings 116 may also be provided for mechanical and electrical connection to load-side circuitry 118 with a load-side cable 120. The bushings 110 and 116, in turn, are connected to the component or component assembly 108. Connector bushings 110, 116 and the like for establishing line and load connections are also well known and are not described in detail herein. Busbars, cables and the like may be used as appropriate to connect the component assembly 108 to the bushings 110, 116 or connectors within the tank 104. Protective elements such as current limiting fuses and other current limiting devices may optionally be provided as desired, either internal to or external to the tank 104. The apparatus 100 may be a single-phase device, a three phase device, or a polyphase device having an appropriate number of bushings 110, 116 for the respective phases of current.

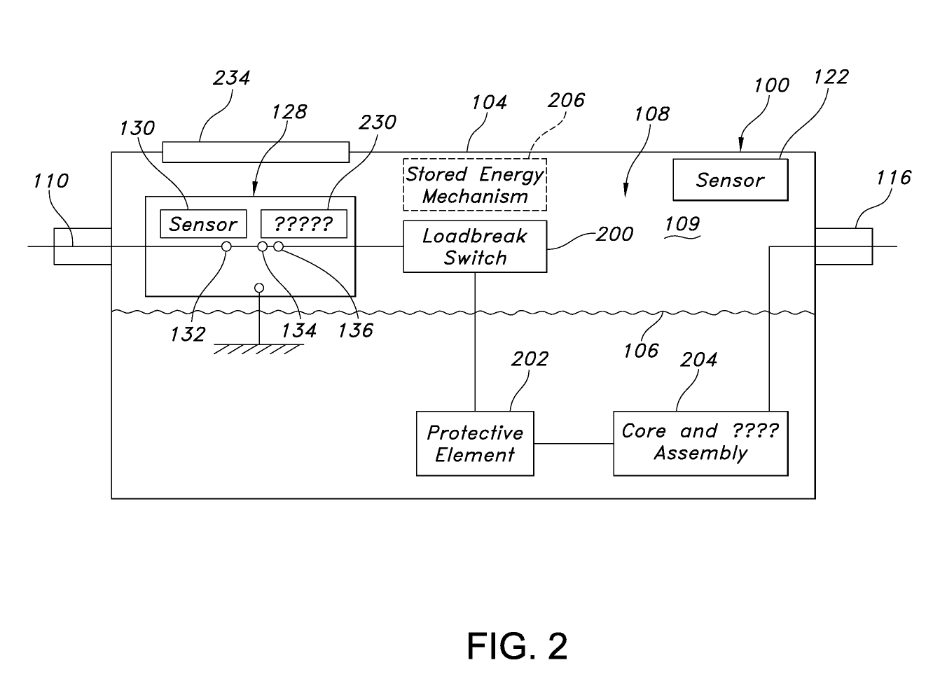

In certain embodiments, the apparatus 100 may be configured as a power distribution transformer, and the component assembly 108, as shown in FIG. 2, may include a switching element 200 such as a loadbreak switch, a protective element 202, and a coil and core assembly 204. A suitable protective element 202 may be, for example, a MAGNEX® interrupter element commercially available from Cooper Power Systems of Waukesha, Wis., although other protective elements may likewise be utilized, including but not limited to other types of interrupters, fuses, breakers, limiters, etc. The switching element 200 may be located in the headspace 109 of the tank 104 above the dielectric fluid 106, while the protective element 202 and the coil and core assembly 204 may be positioned under the surface of the fluid 106, and thus completely surrounded by the fluid 106 in the tank 104. If desired, the switching element 200 may also be positioned under the surface of the fluid 106 in the tank 104 and be immersed in the fluid 106. Still further, the switching element 200 may be located outside of or external to the tank 104 in other embodiments.

Any known switching element, mechanism or component may be used as the switching element 200, including but not limited to sectionalizing switches and loadbreak switches for single phase and polyphase high-voltage systems. The switching element 200 may include a stored energy mechanism 206 for actuating the switch contacts in the switching element 200. The stored energy mechanism 206 may be a known over-toggled spring mechanism that controls rotary motion of a shaft within the switching element to move selectively engage or disengage movable switch contacts with stationary contacts in the switching device. Such high-voltage switching elements and stored energy mechanisms for actuating the switches are more completely described in commonly owned U.S. application Ser. No. 11/304,479 filed Dec. 15, 2005 and entitled MOTORIZED LOADBREAK SWITCH CONTROL SYSTEM AND METHOD, the disclosure of which is hereby incorporated by reference in its entirety. It is contemplated, however, that other known switching elements and actuator mechanisms may likewise be employed as desired.

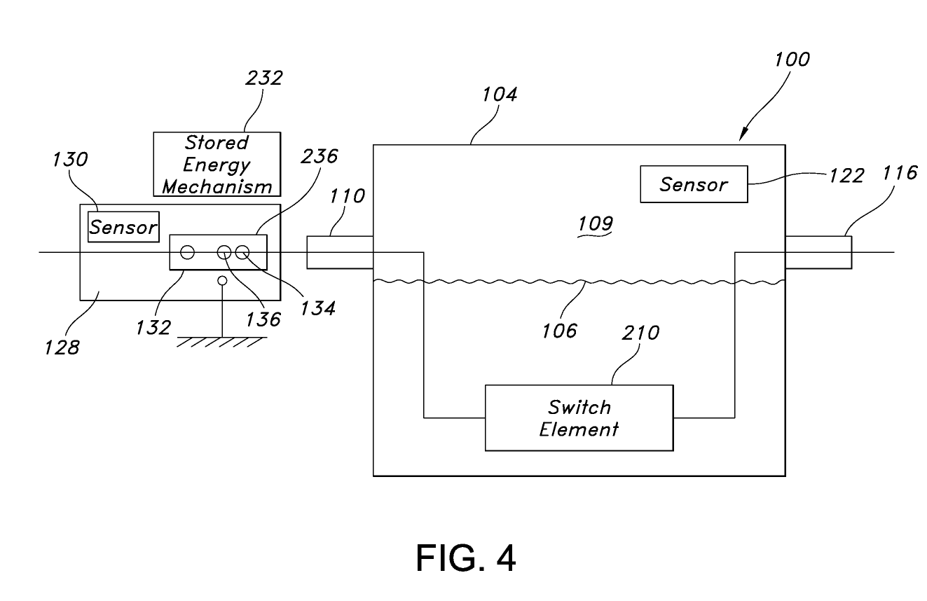

As illustrated in FIG. 4, the apparatus 100 may be also configured as high-voltage switchgear in certain embodiments. In such embodiments, the component assembly 108 may include a switching element, mechanism, device or component 210 that is contained and confined in the tank 104. The switching element 210 may be any of the switching elements and devices previously noted for the switch element 200, or may be still another known switching device if desired. One or more protective devices may be provided in the tank 104 and connected to the switch element 210 as is known in the art, including but not limited to fuses, breaker elements, interrupters, limiters, etc. familiar to those in the art.

While transformer and switchgear embodiments of the apparatus 100 are specifically noted herein, it is contemplated that the apparatus may be configured as other types of electrical apparatus and equipment and include other components insulated with a liquid dielectric inside a tank.

Returning now to FIG. 1, regardless of whether the apparatus 100 is configured as a transformer, switchgear or other piece of electrical equipment, electrical arcing conditions in the tank 104 may result in a rapid and excessive pressure build-up within the tank 104. By detecting electrical arcing and current flowing in the electrical apparatus 100 while electrical arcing is present, the arc suppression system 102 may intervene when certain arcing conditions are presented to limit pressure build-up in the tank to an amount below the pressure withstand capability of the tank 104, thereby ensuring that the tank 104 will not rupture in a fault condition. A duration of arcing conditions is measured by the system 102, and based upon the current magnitude and duration of electrical arcs, problematic arcs may be extinguished to prevent excessive pressure conditions in the tank 104 of the apparatus 100 that may otherwise cause the tank 104 to rupture. Other arcing events that are not problematic, however, will not be acted upon by the system 102 as explained below.

The magnitude or strength of arcs may be evaluated via detection of the presence of arcing in the tank 104, the location of arcs, a duration of sustained arcing conditions, and the amount of current associated with arcing conditions. Based on the strength of arcing conditions, the system 102 may be selectively operated to mitigate or control the pressure build-up in the tank 104 on an as needed basis as arcs occur. In particular, pressure buildup within the tank 104 may be controlled and kept within acceptable limits by reducing a duration of sustained arcing conditions as will become evident below.

As shown in FIG. 1, the arc suppression system 102 may include one or more sensors 122 associated with the apparatus tank 104, a controller 124 responsive to the sensors 122, an actuator 126 responsive to the controller 124, and an arc suppressor device 128 driven by the actuator 126. The arc suppressor device 128 may also include one or more sensors 130.

The sensors 122 may each be a photo-optical sensor or other light sensitive element that may detect light associated with an arc flash occurring within the tank 104. Occurrence of the arc flashes causes the sensors 122 to signal the controller 124 of an electrical arcing condition within the tank 104. While a single sensor 122 may be sufficient to detect electrical arcing within the tank 104, by providing multiple sensors at different locations 122 in the tank 104, the location of arcing within the tank may be determined by the controller 124. The sensors 122 may be located in the tank headspace 109 above the dielectric fluid 106, or alternatively may be located in the fluid 106 if desired with appropriate sealing measures taken to preserve the integrity of the sensors 122.

In different embodiments, the controller 124 may be provided proximate to the sensors 122, or the controller 124 may be located remotely from the sensors 122. The light-detecting sensors 122 may provide a control input to the controller 124 in a known manner using, for example, a hard-wired connection, a wireless communication technique such as radio frequency (RF) signal transmission techniques or other wireless schemes, fiber-optic signal transmission, and the like known in the art.

The controller 124 may be for example, a microcomputer or other processor-based device. The controller 124 may include a microprocessor 123 and a memory 125 for storing instructions, calibration constants, control algorithms and other information as required to satisfactorily operate the arc suppressor device 128 in the manner explained below. The controller memory 125 may be, for example, a random access memory (RAM), or other forms of memory used in conjunction with RAM memory, including but not limited to flash memory (FLASH), programmable read only memory (PROM), and electronically erasable programmable read only memory (EEPROM).

The arc suppressor device 128 may include a contact assembly having a first or main contact 132, a second electrical contact 134 mounted in a fixed or stationary relationship to the main contact 132, and a third movable contact 136 that in normal use conditions completes an electrical connection between the main contact 132 and the second contact 134. The first contact 132 is electrically connected to the line circuitry 112, and the second contact 134 is electrically connected to the line-side bushing 110 of the apparatus 100 in an exemplary embodiment. A current path or circuit path is therefore completed through the arc suppressor device 128 between the line-side circuitry 112 and the apparatus 100. One set of contacts 132, 134 and 136 may be provided for each respective phase of current supplied to the apparatus 100.

The sensors 130, in one embodiment, may each be a known current sensor, such as a current transformer, that monitors and detects current flow through the arc suppressor 128 and the associated electrical apparatus 100. In one embodiment, current flow from the main contact 132 to the second contact 134 in the contact assembly is monitored. Other known current sensors, including but not limited to Rogowski coils and the like, may alternatively be utilized as the sensors 130 in other embodiments at the same of other location to monitor current flow in the apparatus 100. In one exemplary embodiment, a sensor or sensors 130 may be located internal to the arc suppressor device 128 as illustrated, or alternatively may be located external to the arc suppressor device 128 if desired.

Similarly, the controller 124 may be provided proximate to the sensors 130, or the controller 124 may be located remotely from the sensors 130. The sensors 130 may provide a control input to the controller 124 in a known manner using, for example, a hard-wired connection, a wireless communication technique such as radio frequency (RF) signal transmission techniques or other wireless schemes, fiber-optic signal transmission, and the like known in the art.

The controller 124 therefore accepts or receives input signals from the sensors 122 and 130, respectively, for monitoring of the presence of electrical arcs in the tank 104 via the sensors 122, and for monitoring of the current flow associated with electrical arcing conditions via the sensors 130. Based upon the magnitude of the current detected with the sensor 130 and/or the duration of arcing in the tank 104, the controller 124 may operate the actuator 126 to move the movable contact 136 of the arc suppressor device 128 away from the second contact 134. Movement of the movable contact 136 completes an electrical connection or circuit path (represented by the dashed line in FIG. 1), via the movable contact 136, to earth ground. The electrical apparatus 100 may therefore be isolated from the line circuitry 112 and the arcing condition within the tank is accordingly extinguished, preventing the arc from creating internal pressure within the tank 104 that could otherwise cause it to rupture.

The actuator 126 may be a stored energy device such as a squib 230 (FIG. 2) including a power charge, for example that may be ignited to generate explosive force on the movable contact 136 to complete the electrical connection to ground. As another example, the actuator 126 may be a spring loaded mechanism 232 (FIG. 4) similar to the mechanism 206 described in relation to FIG. 2) to position movable switch contacts relative to stationary contacts to complete the electrical connection to ground. Still other known actuators may be utilized in other embodiments to move the movable contact 136 of the arc suppressor device 128 from its normally closed position with the second contact 134 to the open position completing an electrical connection to earth ground. In different embodiments, the actuator 126 may be integral to the arc suppressor 128 or may be separately provided. More than actuator 126 may be provided to actuate the same or different movable contacts to complete the circuit path to ground.

The arc suppression system may also include a power supply 138 coupled to the controller 124 and perhaps the sensors 122 used to sense conditions in the tank 104. If desired, the power supply 138 may also supply energy to the actuator 126 to facilitate movement of the contact 136 to short current to ground. The power supply 138, in various embodiments, may be power sources such as batteries, mini-fuel cells, electrostatic couples, capacitors, power harvesting devices and the like familiar to those in the art.

While the system 102 depicted in FIG. 1 (and also in FIG. 4) is generally located apart from and outside of the apparatus 100, it is contemplated that one or more of the controller 124, the actuator 126, the suppressor device 128, the sensor 130 and the power supply 138 may be located inside the apparatus tank 104 in some embodiments, such as in FIG. 2 wherein the arc suppressor 128 is illustrated inside or internal to the tank 104. As explained below, the arc suppressor 128, controller 124, actuator 126, and power supply 138 may be provided in a single package and may be located within the headspace 109 of the apparatus tank 104. In other embodiments, these components may even be located under the fluid 106 that insulates the apparatus 100. Because the fluid 106 can be very warm in use at temperatures of 1200° C. or more, particular attention must be paid in such an embodiment to ensure proper operation of the electronics in this environment.

Locating the electronics of the system 102 in the headspace 109 within the tank 104 may be preferable because the operating temperatures in the headspace 109 are typically less than 85° C. Mounting of the system components can be made to grounded surfaces in the apparatus 100, which may include a handhole cover 234 (FIG. 2). When the cover 234 is removed, the system components may be easily accessed at the site of the apparatus 100. In such an embodiment, the controller electronics and power supply, for example, may be conveniently accessed for service, programming, replacement, or repair.

The power supply 138 and the logic electronics or controller 124 could alternatively be mounted to a front plate of the apparatus 100, or in a cable termination cubicle inside the tank 104, making replacement or service or the power supply or logic electronics even easier.

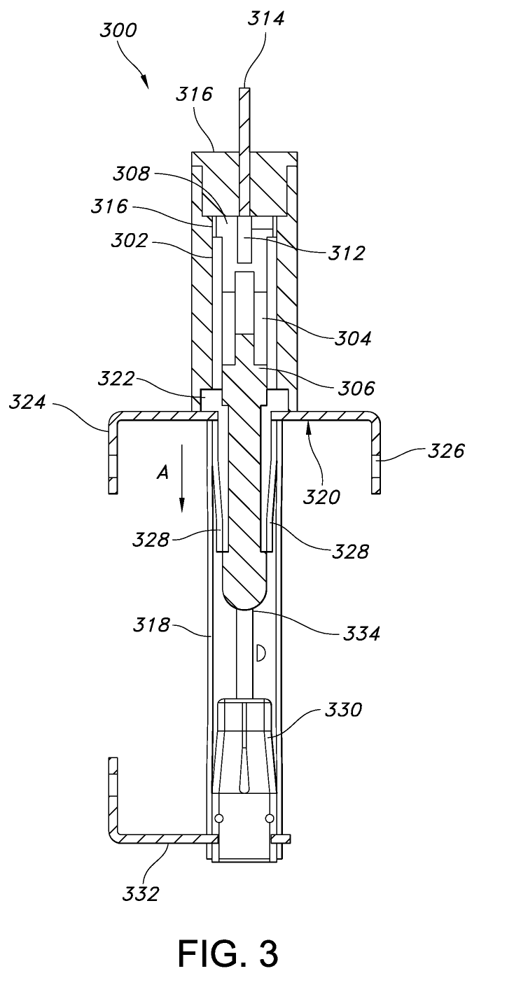

FIG. 3 is a cross sectional view of one embodiment of a contact assembly 300 that may be utilized as the arc suppressor device 128. The contact assembly includes a housing 302, a plunger 304 received in the housing 302, and a movable contact 306 coupled to the plunger. An end 308 of the plunger 304 is maintained in a stationary position relative to the housing 302 via a retainer portion and seals 310. A squib 312 is contained within a bore in the plunger 304 extending from the end 308, and ignition leads 314 extend from the squib 312. An insulating plug 316 is fitted into and closes one end of the housing 302 adjacent the plunger 304 to protect the leads 314 and the squib 312. The leads 314 are connected to the controller 124 and/or the power supply 138 (FIG. 1) for actuation or operation of the contact assembly 300 as described below.

The movable contact 306 may be probe or piston-shaped as shown in FIG. 3, and the contact 306 extends axially from the plunger 304 into a slotted spacer tube 318. A contact bus 320 is fitted to a lower end of the housing 306 opposite the plug 316 and is held in place with a fastener 322 such as a nut. The bus 320 is formed with a line-side connection portion 324 and a load-side connector portion 326. The line-side connecting portion 324 and the load-side connecting portion 326 provide connection points for a line-side cable and the component 108 (FIG. 1) within the tank 104 of the apparatus 100. As such, the line-side connecting portion 324 and the load-side connecting portion 326 correspond to the main contact 132 and the second contact 134 (FIG. 1) of the arc suppressor 128, while the movable contact 306 corresponds to the movable contact 136 as shown in FIG. 1.

Deflectable contact arms 328 mechanically and electrically engage the movable contact 306 and complete an electrical connection between the line-side connection portion 324 and the load-side connection 326 of the contact bus 320. In normal use conditions, the movable contact 306 is mechanically constrained to the position shown in FIG. 3, and a conductive path through the contact bus 320 and the contact 306 is maintained.

A female contact 330 is provided in the tube 318 opposite of the movable contact 306 and is spaced from a leading end 334 of the movable contact 306 by a predetermined distance D of about 1.5 inches in an exemplary embodiment. A ground contact 332 is mechanically and electrically connected to the female contact 330 and provides a site for connection to earth ground.

When undesirable arcing conditions are detected with the sensors 122 and 130 (FIG. 1), energy is supplied to the leads 314 of the squib 312 to ignite or detonate the squib 312. The energy may be supplied by the controller 124 or the power supply 138 as shown in FIG. 1. Ignition or detonation of the squib 312 explosively severs the seals 310 and releases the movable contact 306 for movement relative to the housing 302 and the tube 318. Forces generated by detonation of the squib 312 cause the released contact 306 to move downwardly in the direction of arrow A in FIG. 1 so that the leading end 334 of the contact 306 is moved closer to the female contact 330 provided at the lower end of the tube 318.

As the distal end 334 of the movable contact 306 approaches and mechanically and electrically engages the female contact 330, a current path is established between the contact 306 and to the female contact 330 connected to ground via the ground contact 332. As such, current flowing through the contact 306 may be shorted to ground.

When the distal end 334 of the movable contact 306 is fully received in the female contact 330, the contact arms 328 providing the electrical connection through the contact bus 320 are connected through the top of the contact 306. This maintains the solid connection to ground, shorting the electrical power entering the tank directly to ground. As a result, any electrical arcing in the tank 104 is eliminated or extinguished before excessive pressure build-up in the tank 104 may occur. Potential rupturing of the tank 104 is therefore avoided.

The benefits of the contact assembly 300 when used with the arc suppression system 102 are numerous. The contact assembly 300 and the arc suppression system 102 may be configured to operate only when electrical arcing is present in the tank 104 that has a sufficient current magnitude or long enough duration that the tank pressure withstand capacity is threatened. That is, the system 102 may be configured so that it operates only due to an arcing failure condition within the tank 104, while ignoring or not responding to arcing conditions that do not threaten the integrity of the tank 104. Other fuses and protective devices such as primary breakers may be utilized in combination with the contact assembly 300, and the protective devices may operate on overloads and secondary faults, or on core/coil failures, for example, that affect the transformer or other equipment. In such a manner, the apparatus 100 or other equipment may be electrically isolated from faults, while leaving the cable loop in place, carrying power to the rest of the system. Such protective devices may be provided at lower cost than expensive protective devices such as large fuses conventionally used to protect a core and coil assembly in power distribution transformers.

The contact assembly 300 also may be provided at relatively low cost, may occupy minimal space in the tank 104, and may be provided in critical areas of the apparatus when configured as a transformer, as switchgear, or as other electric power distribution equipment. In particular, the contact assembly 300 may be conveniently connected to the high-voltage bushing 110 (FIG. 1) which brings electrical power from the cables of the power distribution system into the apparatus. The contact assembly 300 may be easily installed and with easily accessed connections to the line-side cable loop and the core/coil lead via the portions 324 and 326 of the contact bus 322.

If the arc suppression system 102 operates or actuates the contact assembly 300 to complete the electrical connection to earth ground, the cable loop connection system may be configured to bypass the apparatus 100 and restore service to the rest of the power network while the failed apparatus 100 is being replaced.

In some embodiments, the controller 124 the sensor 130, and the power supply 138 may be mounted directly on the contact assembly 300 and provided in an integral package. When used in such a manner, the sensor 130, the controller 124, and the power supply 128 may be electrically isolated from the effects of high-voltage, using the clearance and isolation provided by the high-voltage bushing 110. That is, the sensor 130, the controller 124, the actuator 126 and the power supply 138 may be located in the headspace 109 of the apparatus tank 104. Additionally, because the squib leads 314 are insulated and isolated from the high-voltage of the movable contact 306, the power supply 138 for the and the controller 124 for the arc-suppressor need not be directly connected to high-voltage components 108 in the apparatus 100.

FIG. 4 illustrates another embodiment of the arc suppressor 128 for the system 102 described above, wherein the contacts 132, 134 and 136 are contained in a switching element 236 mounted exterior to the tank 104 of the apparatus 100. The switching element 236 containing the contacts 132, 134 and 136 may be any of the switching elements, switching units, switching components, or switching mechanisms described above. The stored energy mechanism 232, described above, may be provided to actuate the movement of the contact 136 to complete an electrical connection to ground. While the switching element 236 is illustrated in FIG. 4 as being external to or outside of the tank 104, it is understood that the switching element 236 that functions as the arc suppressor 128 may alternatively be located inside the tank.

### IV. Inventive Control Methods for the System

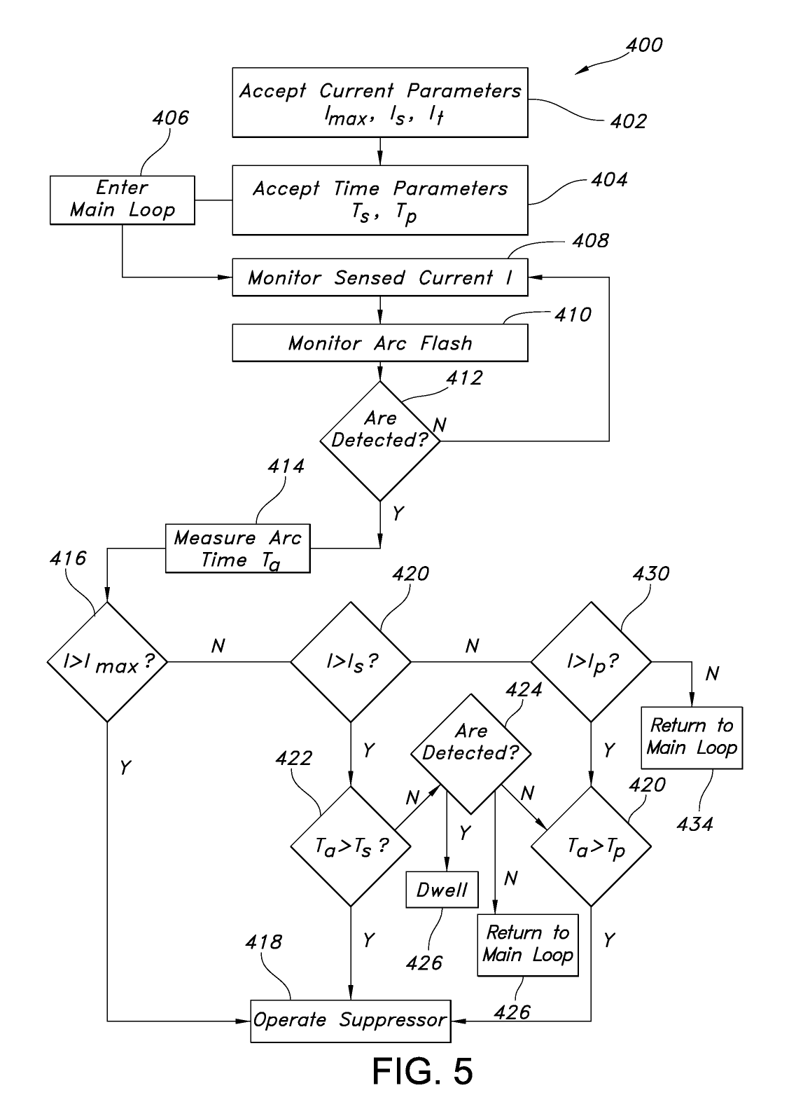

FIG. 5 is a method flowchart of an exemplary control algorithm for the arc suppression system 102 shown in FIG. 1, and in particular will be explained in relation to the apparatus 100 configured as shown in FIG. 2 into a power distribution transformer.

For effective control of the arc suppression system the components of the apparatus 100 should be taken into account, together with the detection of electrical arcing conditions in the apparatus, a measured duration of electrical arcing conditions, and sensed current levels at the time that arcing is present. Normal operation of the components in the apparatus may produce electrical arcs within the apparatus tank that pose no threat to the pressure withstand capability of the tank, and that are fully expected in use. Thus, operating characteristics of the active components in the apparatus may be utilized to distinguish normal or expected electrical arcing from abnormal electrical arcing, which may occur for example when any of the active components in the apparatus fails. As such, the arc suppression system may respond to unacceptable electrical arcing events while ignoring acceptable arcing events.

Considering the apparatus shown in FIG. 2, the active components include a loadbreak switch, a protective element, and a core and coil assembly. When the loadbreak switch is closed to complete a line-side connection to the transformer, an inrush current to the transformer may be experienced that is much greater than the current carried by the switch in normal operating conditions. In one example, the inrush current may be considered to be about 25 times the normal operating current. Currents exceeding this amount would be indicative of an abnormality in the apparatus, and thus the maximum inrush current could be considered a maximum current Iₘₐₓ that the arc suppression system would tolerate without taking action. While the normal operating current may vary for different types of equipment and apparatus in various locations in a power distribution network, in an illustrative embodiment, the normal operating current may be about 400 A. An expected inrush current as the switch is closed may be up to 25 times this amount, resulting in an Iₘₐₓ for the arc suppression system of 10 kA. Arcing conditions involving currents exceeding Iₘₐₓ may be acted upon by the arc suppression system without regard to a measured duration of the arc. Alternatively stated, the arc duration necessary to trigger the arc suppression system when sensed current exceeds Iₘₐₓ is effectively any non-zero value.

For purposes of the arc suppression system, the loadbreak switch is operable at currents less than Iₘₐₓ but above the maximum interrupting current of the protective element. The maximum interrupting current of the protective element may be considered a lower bound Iₛ for operation of the switch insofar as the arc suppression system is concerned. In a particular embodiment, the maximum interrupting current of the protective element is 3.5 kA, although other values are possible for other protective elements. Detected arcing conditions when sensed currents are between Iₘₐₓ and Iₛ indicate that arcing conditions are associated with operation of the switch and not the protective element.

Operation of the loadbreak switch in the apparatus also is pertinent to the arc suppression system for its effect in limiting arc duration during normal closing of the switch contacts. In particular, the time required to completely close the switch contacts may be used as a baseline Tₛ for distinguishing a normal and expected arc occurring during closing of the switch contacts from an abnormal or unexpected arc that the arc suppression system must act upon. In one particular embodiment, the loadbreak switch would be expected to close within one-half cycle of arcing in normal operation and Tₛ would be 0.02 seconds, although other values are possible for different switches. Arcing for more than a duration of Tₛ indicates an internal fault in the switch, provided that the sensed current is within a range between Iₘₐₓ and Iₛ as noted above.

The protective element is pertinent to operation of the arc suppression system in that when sensed current through the arc suppression device is below Iₛ, the protective element will generally trip and operate normally on secondary faults and overloads that are anticipated in the design of the transformer. When the protective elements trips and operates in such conditions, internal arcing in the protective element will not occur and the arc suppression system does not operate. If, however, arcing conditions are detected in such conditions, an internal fault is likely present in the protective element and the arc suppression system may need to act to avoid excessive pressure build-up in the apparatus tank.

A lower current baseline Iₚ that is less than the Iₛ may be established as a lower limit to operation of the arc suppression system. Iₚ corresponds to a current level wherein electrical arcing conditions present no threat to the integrity of the apparatus tank. Iₚ may be empirically determined for a particular tank design, and in a particular embodiment an Iₚ value of 300 A has been found to be adequate and appropriate. At sensed current levels below Iₚ the arc suppression system will not act.

The amount of time necessary for the protective element to trip or operate is also relevant to the control of the arc suppression system. This may be used as a baseline Tₚ to evaluate whether the protective element is operating normally or abnormally, provided that the sensed current is between Iₛ and Iₚ. In one embodiment, the protective element requires about 0.1 seconds to fully clear a secondary fault or overload, although other elements may require a greater or lesser amount of time. When the sensed current is between Iₛ and Iₚ, the arc suppression system should delay its operation for at least the period of Tₚ to provide an adequate opportunity for the protective element to function.

Having now explained some of the parameters utilized by the system, a method algorithm 400 executable by the arc suppression system controller will be explained in relation to FIG. 5.

The algorithm begins by accepting 402 the current baseline parameters Iₘₐₓ, Iₛ and Iₚ and loading the parameters into the controller memory. The time baseline parameters Tₛ and Tₚ also are accepted 404 and loaded in the controller memory. Once the parameters are accepted 402 and 404 and the controller is powered up, the controller enters 406 a main control loop.

In the main control loop, the sensed current I is monitored 408 via the current sensor signal input(s) to the controller, and the apparatus tank is monitored 410 by the controller via the light-detecting sensor signal input(s) to the controller. The controller awaits 412 a signal from the light-detecting sensor or sensors that electrical conditions are occurring in the tank before undertaking further processing of the input signals from sensors. If electrical arcing is detected, the controller sets a timer to measure 414 a time duration of the signal from the light detecting sensors, which corresponds to a time duration Tₐ of the detected arcing conditions in the tank. After setting the time, the controller determines 416 whether the sensed current I is greater than Iₘₐₓ.

If I is greater than Iₘₐₓ then the controller signals the actuator to operate 418 the arc suppressor and position the movable contact therein to short the current I to ground. As noted above, this condition indicates current beyond anticipated current inrush conditions and an abnormality or fault with potentially severe consequences that the controller responds to immediately without regard to the measured duration of arcing. That is, any nonzero value for the measured arc duration Tₐ in this current range is sufficient to cause the controller to operate the arc suppressor.

If I is less than Iₘₐₓ then the controller proceeds to determine 420 whether the sensed current I is greater than the current baseline Iₛ for operation of the switch. If I is greater than Iₛ the controller determines 422 whether the measured arc duration Tₐ is greater than Tₛ for normal operation of the switch. If Tₐ is not greater than Tₛ the controller again determines whether 424 whether arcing is still being detected in the apparatus. If arcing is still detected, the controller enters 426 a dwell or waiting period until the measured arc duration Tₐ exceeds Tₛ in step 422 or until the arc is no longer detected in step 424, whichever occurs first.

When the measured arc duration Tₐ exceeds the normal switch time Tₛ while arcing conditions remain detected, the controller proceeds to operate 418 the arc suppressor to short the current I to ground. These conditions indicate a fault condition in the switch.

If the arc at any point before the measured arc duration Tₐ exceeds the normal switch time Tₛ arcing is no longer detected at step 424, the controller returns 428 to the main loop and starts over.

If at step 420 the sensed current I is less than the current baseline Iₛ of the switch, the controller determines 430 whether the sensed current I is greater than the low current baseline Iₚ of the protective element.

If the sensed current I is greater than Iₚ for the protective element, the controller determines 432 whether the measured arc duration Tₐ is greater than Tₚ for normal operation of the protective element. If Tₐ is not greater than Tₚ the controller again determines whether 424 whether arcing is still being detected in the apparatus. If arcing is still detected, the controller enters 426 a dwell or waiting period until the measured arc duration Tₐ exceeds Tₚ in step 432 or until the arc is no longer detected in step 424, whichever occurs first.

When the measured arc duration Tₐ exceeds the normal protective element trip or operation time Tₚ while arcing conditions remain detected, the controller proceeds to operate 418 the arc suppressor to short the current I to ground. These conditions indicate a fault condition in the protective element.

If the arc at any point before the measured arc duration Tₐ exceeds the normal switch time Tₚ arcing is no longer detected at step 424, the controller returns 434 to the main loop and starts over.

If at step 430 the sensed current I is less than the baseline parameter Iₚ for the protective element, the controller returns 434 to the main loop and starts over.

As should now be evident, detection of some arcs at step 412 will cause the controller to operate the arc suppressor device while others will not. Whether or not the controller intervenes to operate the successor is dependent upon sensed current conditions, measured duration of arcing conditions, and the operating characteristics of the switch and the protective element in the apparatus being protected.

Having now described the control algorithm 400 in some detail, it is believed that those of ordinary skill in the art could program the algorithm and implement the controller instructions without further explanation.

While an exemplary algorithm has been described, it is contemplated that other inputs and control parameters may be provided and utilized to make control decisions. For instance, when the actuator for the switch element is a spring-loaded over-toggled switch mechanism, a rotation of the switch could also be sensed and input to the controller to evaluate whether arcing is due to a fault condition within the tank or elsewhere on the cable system. Sensing elements and control algorithms for detecting rotation of such a switch mechanism are disclosed in commonly owned U.S. application Ser. No. 11/304,479 filed Dec. 15, 2005 and entitled MOTORIZED LOADBREAK SWITCH CONTROL SYSTEM AND METHOD, the disclosure of which is hereby incorporated by reference in its entirety.

It is also contemplated that less than all of the inputs and control parameters in the algorithm 400 may likewise be employed with similar effect. For example, when protective elements are not utilized in the apparatus, the parameters Iₚ and Tₚ may be omitted and associated steps involving such parameters may be eliminated.

Data logging steps may additionally be performed by the controller wherein detected arcing conditions and quantitative results of the various comparison steps are recorded in the controller memory for later review and analysis. The controller may also be coupled to an indicator on the apparatus to positively indicate the controller's determination of which component in the apparatus prompted the fault condition. The controller's determination of the fault condition may be communicated to a remote operating system and may be used generate alerts to maintenance personnel and system operators to quickly replace faulty components and equipment.

### V. Conclusion

The benefits and advantages of the invention are now believed to be amply demonstrated in the various embodiments disclosed.

An embodiment of an arc suppression system for a high-voltage electrical apparatus including at least one electrical component immersed in a liquid dielectric fluid is disclosed. The arc suppression device comprises: a contact assembly comprising a line contact, a ground contact spaced from the line contact, and a movable contact mounted stationary to the line contact for normal operation of the electrical component; and a stored energy element adapted to position the movable contact to complete an electrical connection between the line contact and the ground contact when the electrical component fails and generates an electrical arc of a designated magnitude and duration.

Optionally, the stored energy element may comprise a squib, a spring loaded mechanism, or a container containing a high-pressure gas. A sensor configured to detect an arc flash may be provided, and a sensor detecting a current flow through the electrical component may also be provided. A controller may be operatively connected to the stored energy element, with the stored energy element responsive to the controller to position the movable contact when a failure of the electrical component is detected. The controller may be configured to operate the stored energy element in response to a monitored current level for the line contact, a detected arc flash, and a detected arc duration. The system may further comprise a power supply, wherein the power supply is selected from the group of a battery, a fuel cell, an electrostatic couple, a capacitor and a power harvesting device. The apparatus may comprise a power distribution transformer or switchgear. The apparatus may include a protective element and a high-voltage bushing, with the arc suppression device connected to the bushing. The liquid dielectric fluid may comprise a mineral oil, a vegetable oil, a polyolester fluid, a silicone fluid, or mixtures thereof, or other insulative fluids known in the art.

An embodiment of an arc suppression system for a high-voltage electrical apparatus including a tank and at least one electrical component immersed in a liquid dielectric fluid within the tank is also disclosed. The arc suppression device comprises: a controller; a light detecting sensor coupled to the controller and located to detect a presence of electrical arcing in the tank; a current sensor coupled to the controller and monitoring a current flow to the electrical component; and an arc suppressor device connected to the apparatus and responsive to the controller to complete a circuit path to electrical ground and extinguish the arcing when the monitored current exceeds a specified level and when the detected arcing exceeds a specified duration.

Optionally, the arc suppressor device may comprise a contact assembly, that may comprise a line contact, a ground contact spaced from the line contact, and a movable contact mounted stationary to the line contact for normal operation of the electrical component. A stored energy element may be adapted to position the movable contact to complete an electrical connection between the line contact and the ground contact when the specified current level and the specified duration are met. The system may comprise a power supply, wherein the power supply is selected from the group of a battery, a fuel cell, an electrostatic couple, a capacitor and a power harvesting device. The apparatus may comprise a power distribution transformer, or switchgear. The apparatus may include a protective element and a high-voltage bushing, with the arc suppression device connected to the bushing. The liquid dielectric fluid comprises a mineral oil, a vegetable oil, a polyolester fluid, a silicone fluid, or mixtures thereof, or other insulative fluids known in the art.

An embodiment of a high-voltage arc suppression system is also disclosed. The system comprises: a high-voltage electrical apparatus including a tank and at least one electrical component immersed in a liquid dielectric fluid within the tank; an arc suppressor device comprising a contact assembly including a line contact, a ground contact spaced from the line contact, and a movable contact mounted stationary to the line contact for normal operation of the electrical component; an actuator element configured to move the movable contact to complete an electrical connection between the line contact and the ground contact when specified arcing conditions occur in the tank; a controller operationally connected to the actuator element; a light detecting sensor coupled to the controller and located to detect a presence of electrical arcing in the tank; and a current sensor coupled to the controller and monitoring a current flow to the electrical component; wherein the controller operates the actuator in response to detected arcing conditions, detected current levels, and measured duration of arcing conditions.

Optionally, the arc suppressor device is located internal to the tank. The apparatus may include a high-voltage bushing, with the arc suppressor device connected to the bushing. The actuator element may comprise a squib. The apparatus may further comprise a switch and a protective element, with the controller being programmed to account for operating characteristics of the switch and the protective element prior to operating the actuator in response to detected arcing conditions, detected current levels, and measured duration of arcing conditions.

A method of controlling an arc suppression system configured to detect an occurrence of arcing conditions inside a liquid-filled tank of a high-voltage electrical apparatus is also disclosed. The arc suppression system may be further configured to sense electrical current conditions in the apparatus and to complete a circuit path to ground when a fault condition is present, with the method comprising: detecting the presence of electrical arcing inside the tank; detecting a current level contemporaneous with the detected arcing; comparing the detected current level to a first predetermined threshold level; and completing the circuit path to ground when the detected current level exceeds the first predetermined threshold level, thereby extinguishing the detected electrical arcing.

Optionally, the method may further comprise: measuring a duration of detected electrical arcing; comparing the measured duration of detected electrical arcing to a predetermined baseline value; and completing the circuit path to ground only when the measured duration exceeds the predetermined baseline value and when the detected current level exceeds the first predetermined threshold level. Completing the circuit path to ground may comprise detonating a squib.

The method may also optionally comprise: comparing the detected current level to a second predetermined threshold level when the detected current level is less than the first predetermined threshold level; and completing the circuit path to ground when the detected current level is greater than the second predetermined threshold level. The method may also optionally comprise: measuring a duration of detected electrical arcing; comparing the measured duration of detected electrical arcing to a predetermined baseline value; and completing the circuit path to ground only when the measured duration exceeds the predetermined baseline value and when the detected current level exceeds the second predetermined threshold level.

Also disclosed is an arc suppression system comprising: means for detecting electrical arcing conditions inside a liquid-filled tank of an electrical apparatus; means for detecting current flow in the apparatus; means for measuring a duration of detected electrical arcing; means for completing a circuit path to ground to extinguish detected electrical arcing; and means for determining whether to operate the means for completing a circuit path in response to detected current flow and measure arc duration of detected electrical arcing conditions; wherein the means for deciding responds to certain electrical arcing conditions while ignoring other detected arcing conditions.

Optionally, the system may further comprise means for actuating the means for completing the circuit path. The system may also comprise means for supplying power to at least a portion of the arc suppression system.

While the invention has been described in terms of various specific embodiments, those skilled in the art will recognize that the invention can be practiced with modification within the spirit and scope of the claims.

What is claimed is:

1. An arc suppression system for a high-voltage electrical apparatus including at least one electrical component immersed in a liquid dielectric fluid, the arc suppression device comprising:
a contact assembly comprising a line contact, a ground contact spaced from the line contact, and a movable contact mounted stationary to the line contact for normal operation of the electrical component; and
a stored energy element adapted to position the movable contact to complete an electrical connection between the line contact and the ground contact when the electrical component fails and generates an electrical arc of a designated magnitude and duration.

2. The arc suppression system of claim 1, wherein the stored energy element comprises a squib.

3. The arc suppression system of claim 1, wherein the stored energy element comprises a spring loaded mechanism.

4. The arc suppression system of claim 1, wherein the stored energy element comprises a container containing a high-pressure gas.

5. The arc suppression system of claim 1, further comprising a sensor configured to detect an arc flash.

6. The arc suppression system of claim 1, further comprising a sensor detecting a current flow through the electrical component.

7. The arc suppression system of claim 1, further comprising a controller, the controller operatively connected to the stored energy element, and the stored energy element responsive to the controller to position the movable contact when a failure of the electrical component is detected.

8. The arc suppression system of claim 7, wherein the controller is configured to operate the stored energy element in response to a monitored current level for the line contact, a detected arc flash, and a detected arc duration.

9. The arc suppression system of claim 1, further comprising a power supply, wherein the power supply is selected from the group of a battery, a fuel cell, an electrostatic couple, a capacitor and a power harvesting device.

10. The arc suppression system of claim 1, wherein the apparatus comprises a power distribution transformer.

11. The arc suppression system of claim 1, wherein the apparatus comprises switchgear.

12. The arc suppression system of claim 1, wherein the apparatus includes a protective element.

13. The arc suppression system of claim 1, wherein the apparatus comprises a high-voltage bushing, the arc suppression device connected to the bushing.

14. The arc suppression system of claim 1, wherein the liquid dielectric fluid comprises a mineral oil, a vegetable oil, a polyolester fluid, a silicone fluid, or mixtures thereof, or other insulative fluids known in the art.

15. An arc suppression system for a high-voltage electrical apparatus including a tank and at least one electrical component immersed in a liquid dielectric fluid within the tank, the arc suppression device comprising:
a controller;
a light detecting sensor coupled to the controller and located to detect a presence of electrical arcing in the tank;
a current sensor coupled to the controller and monitoring a current flow to the electrical component; and
an arc suppressor device connected to the apparatus and responsive to the controller to complete a circuit path to electrical ground and extinguish the arcing when the monitored current exceeds a specified level and when the detected arcing exceeds a specified duration.

16. The arc suppression system of claim 15, wherein the arc suppressor device comprises a contact assembly comprising a line contact, a ground contact spaced from the line contact, and a movable contact mounted stationary to the line contact for normal operation of the electrical component.

17. The arc suppression system of claim 15, further comprising a stored energy element adapted to position the movable contact to complete an electrical connection between the line contact and the ground contact when the specified current level and the specified duration are met.

18. The arc suppression system of claim 15, further comprising a power supply, wherein the power supply is selected from the group of a battery, a fuel cell, an electrostatic couple, a capacitor and a power harvesting device.

19. The arc suppression system of claim 15, wherein the apparatus comprises a power distribution transformer.

20. The arc suppression system of claim 15, wherein the apparatus comprises switchgear.

21. The arc suppression system of claim 15, wherein the apparatus includes a protective element.

22. The arc suppression system of claim 15, wherein the apparatus comprises a high-voltage bushing, the arc suppression device connected to the bushing.

23. The arc suppression system of claim 15, wherein the liquid dielectric fluid comprises a mineral oil, a vegetable oil, a polyolester fluid, a silicone fluid, or mixtures thereof, or other insulative fluids known in the art.

24. A high-voltage arc suppression system comprising:
a high-voltage electrical apparatus including a tank and at least one electrical component immersed in a liquid dielectric fluid within the tank;
an arc suppressor device comprising a contact assembly including a line contact, a ground contact spaced from the line contact, and a movable contact mounted stationary to the line contact for normal operation of the electrical component;
an actuator element configured to move the movable contact to complete an electrical connection between the line contact and the ground contact when specified arcing conditions occur in the tank;
a controller operationally connected to the actuator element;
a light detecting sensor coupled to the controller and located to detect a presence of electrical arcing in the tank; and
a current sensor coupled to the controller and monitoring a current flow to the electrical component;
wherein the controller operates the actuator in response to detected arcing conditions, detected current levels, and measured duration of arcing conditions.

25. The system of claim 24, wherein the arc suppressor device is located internal to the tank.

26. The system of claim 24, wherein the apparatus includes a high-voltage bushing, the arc suppressor device connected to the bushing.

27. The system of claim 24, wherein the actuator element comprises a squib.

28. The system of claim 24, wherein the apparatus further comprises a switch and a protective element, the controller programmed to account for operating characteristics of the switch and the protective element prior to operating the actuator in response to detected arcing conditions, detected current levels, and measured duration of arcing conditions.

29. A method of controlling an arc suppression system configured to detect an occurrence of arcing conditions inside a liquid-filled tank of a high-voltage electrical apparatus, the arc suppression system further configured to sense electrical current conditions in the apparatus and to complete a circuit path to ground when a fault condition is present, the method comprising:
detecting the presence of electrical arcing inside the tank;
detecting a current level contemporaneous with the detected arcing;
comparing the detected current level to a first predetermined threshold level; and
completing the circuit path to ground when the detected current level exceeds the first predetermined threshold level, thereby extinguishing the detected electrical arcing.

30. The method of claim 29, further comprising:
measuring a duration of detected electrical arcing;
comparing the measured duration of detected electrical arcing to a predetermined baseline value; and
completing the circuit path to ground only when the measured duration exceeds the predetermined baseline value and when the detected current level exceeds the first predetermined threshold level.

31. The method of claim 30, wherein completing the circuit path to ground comprises detonating a squib.

32. The method of claim 30, further comprising:
comparing the detected current level to a second predetermined threshold level when the detected current level is less than the first predetermined threshold level; and
completing the circuit path to ground when the detected current level is greater than the second predetermined threshold level.

33. The method of claim 32, further comprising:
measuring a duration of detected electrical arcing;
comparing the measured duration of detected electrical arcing to a predetermined baseline value; and
completing the circuit path to ground only when the measured duration exceeds the predetermined baseline value and when the detected current level exceeds the second predetermined threshold level.

34. An arc suppression system comprising:
means for detecting electrical arcing conditions inside a liquid-filled tank of an electrical apparatus;
means for detecting current flow in the apparatus;
means for measuring a duration of detected electrical arcing;
means for completing a circuit path to ground to extinguish detected electrical arcing; and
means for determining whether to operate the means for completing a circuit path in response to detected current flow and measure arc duration of detected electrical arcing conditions;
wherein the means for deciding responds to certain electrical arcing conditions while ignoring other detected arcing conditions.

35. The system of claim 34, further comprising means for actuating the means for completing the circuit path.

36. The system of claim 34, further comprising means for supplying power to at least a portion of the arc suppression system.
